(19) United States
(12) Patent Application Publication
(10) Pub. No.: US 2006/0273810 A1
(43) Pub. Date: Dec. 7, 2006

(54) Silicon wafer with solderable coating on its wafer rear side, and process for producing it

(76) Inventors: Paul Ganitzer, Villach (AT); Stefan Woehlert, Villach (AT)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/439,749

(22) Filed: May 24, 2006

(30) Foreign Application Priority Data
May 24, 2005 (DE) 10 2005 024 430.0

(51) Int. Cl. G01R 31/02

(52) U.S. Cl. 324/755

(57) ABSTRACT

A silicon wafer with a solderable coating on its wafer rear side and a process for producing it is disclosed. The silicon wafer has integrated circuits on its wafer top side. The rear side coating is free of silver constituents in the immediate vicinity of an adapted gold coating on which a gold/tin solder material is arranged, the volume of gold in the adapted gold coating, together with the volume of gold in the solder material in relation to the volume of tin in the solder material corresponding to the eutectic melt system comprising gold and tin in thermodynamic equilibrium.

### CROSS-REFERENCE TO RELATED APPLICATIONS

This Utility patent application claims priority to German Patent Application No. DE 10 2005 024 430.0 filed on May 24, 2005, which is incorporated herein by reference.

### BACKGROUND

The invention relates to a silicon wafer or a silicon chip with an integrated circuit on its wafer top side or on the top side of the silicon chip. Furthermore, the invention relates to a process for producing a silicon wafer or a semiconductor device with a silicon chip. The rear side of the silicon chip is arranged on a contact connection region of a circuit carrier.

### FIELD OF THE INVENTION

In this context, a circuit carrier is a leadframe with inner and outer flat conductors and a contact connection region for the silicon chip or a wiring substrate with a contact connection region for the rear side of a silicon chip and contact connection surfaces for electrical terminals or connections to the top side of the semiconductor chip.

Document EP 0 072 273 A2 has disclosed a process for attaching an integrated circuit at low temperatures. This process includes coating the rear side of the integrated circuit with silver and coating the surface of the contact connection region of a substrate with at least one of the metals gold, silver, platinum or palladium and applying the coated rear side of the integrated circuit to the coated top side of the substrate with the aid of a molten composition of gold and tin, the gold/tin composition typically comprising 80% by weight gold and 20% by weight tin.

For this purpose, the gold/tin solder material can be applied in unmelted form between the rear side of the integrated circuit and the top side of the substrate, and can then be heated to the melting point of the gold/tin solder material. The molten gold/tin solder material can be applied either to the rear side of the integrated circuit or to the top side of the circuit carrier in accordance with the abovementioned document. An example of this process is shown in FIG. 1.

FIG. 1 illustrates an embodiment with a silicon wafer or silicon chip 1, which on its top side 3 has an integrated circuit and on its rear side 5, in accordance with an embodiment in the prior art according to EP 0 072 273, has a solderable rear side coating 4.1. In accordance with the above prior art, this solderable rear side coating 4.1 has a bonding metal coating 9.1 which directly on the rear side 5 of the semiconductor chip 1 predominately comprises chromium with a residual silver content, the silver content increasing as the thickness of the bonding layer increases, in such a manner that ultimately a silver-containing surface is formed toward a gold/tin solder material 6.1.

FIG. 2 illustrates a contact connection region 8.2 of a circuit carrier to which the rear side coating 4.1 is to be soldered with the aid of the gold/tin solder material 6.1. For this purpose, the contact connection region 8.2 illustrated in FIG. 2 has a diffusion-inhibiting coating 10.2, which is intended to prevent the material of the contact connection region 8.2 from diffusing into the gold/tin solder material 6.1. According to the prior art, this diffusion-inhibiting metal coating 10.2 includes silver, platinum, gold or palladium. When the silicon chip 1 with integrated circuit on its top side 3 and rear side coating 4 is applied to the contact connection region 8.2 with the diffusion-inhibiting metal coating 10.2, the parts which are to be jointed are heated to a sufficient extent for the gold/tin solder material to melt and during cooling for the silicon chip 1 to be fixed on the diffusion-inhibiting metal coating 10.2 in the contact connection region 8.2 of a circuit substrate.

In the associated process of silicon chip mounting on a contact connection region 8.2 with a diffusion-inhibiting metal coating 10.2, two serious fault mechanisms occur. These are firstly what are known as “poor melting”. This poor melting is a type of defect in which the gold/tin solder material does not melt to a sufficient extent. This involves immediately discarding an entire mounting batch if better melting cannot be achieved by increasing the process temperature. However, this increase in the process temperature cannot be transferred to large-area silicon chips since the increase in the process temperature increases the risk of stress-induced crack formation.

The second fault mechanism is known as “peeling” and involves the gold/tin solder material applied cold becoming detached from the silver layer below it. In this case too, the entire mounting batch has to be discarded. Furthermore, it has been possible to establish that the risk of the formation of voids after the application of the silicon chip with its rear side coating to the coated contact connection region is considerable, and consequently the electrical and also thermal coupling between silicon chip and circuit substrate is disadvantageously impaired by the increased thermal and electrical contact resistance in the solder boundary layers.

Since, after completion of a rear side coating of the silicon wafer, it is no longer possible for the rear side coating comprising a gold/tin solder material to be inspected for possible defects, and if a defect is recognized it is also not possible to carry out any reworking, it appears to be crucial for the process of coating the silicon wafer to be carried out without any defects. However, since the defect pictures described above occur in batches with unremarkable process parameters, the entire process appears to be borderline.

For these and other reasons there is a need for the present invention.

### SUMMARY

the present invention provides A silicon wafer with a solderable coating on its wafer rear side and to a process for producing a silicon wafer. In one embodiment, the silicon wafer has integrated circuits on its wafer top side. The rear side coating is free of silver constituents in the immediate vicinity of an adapted gold coating on which a gold/tin solder material is arranged, the volume of gold in the adapted gold coating, together with the volume of gold in the solder material in relation to the volume of tin in the solder material corresponding to the eutectic melt system comprising gold and tin in thermodynamic equilibrium.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a diagrammatic cross section through a silicon wafer or through a silicon chip of a semiconductor device in accordance with the prior art.

FIG. 2 illustrates a diagrammatic cross section through a contact connection region of a circuit carrier of a semiconductor device in accordance with the prior art.

FIG. 3 illustrates a diagrammatic cross section through a silicon wafer or through a silicon chip of a semiconductor device in accordance with one embodiment of the invention.

FIG. 4 illustrates a diagrammatic cross section through a contact connection region of a circuit carrier of the semiconductor device in accordance with the one embodiment of the invention.

FIG. 5 illustrates a diagrammatic cross section through a silicon chip on a contact connection region of the circuit carrier of the semiconductor device in accordance with the one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a silicon wafer and a silicon chip and a semiconductor device which includes this silicon chip. Embodiments of the invention reduce the practical process temperature involved in soldering the silicon chip onto a contact connection region of a circuit carrier by several 10° C. yet achieves a reliable, defect-free connection of the silicon chip rear side to a contact connection surface.

In one embodiment, the invention provides a silicon wafer with an integrated circuit on its wafer top side and a solderable coating on its wafer rear side. The solderable rear side coating includes at least one layer of a gold/tin solder material. Furthermore, the rear side coating remains free of silver constituents in the immediate vicinity of the gold/tin solder material. The gold/tin solder material is arranged on an adapted gold coating, the volume of gold in the adapted gold coating, together with the volume of gold in the solder material in relation to the volume of tin in the solder material corresponding to the eutectic melt system of gold and tin in thermodynamic equilibrium.

The silicon wafer rear side coating, with regard to the gold/tin solder material and the adjacent gold coating or the adjacent gold coatings, is in thermodynamic equilibrium. In this way full use is made of the advantages of the gold/tin diffusion solder system. The precise eutectic melting point is 278° C. However, the system which is known from the prior art is not in thermodynamic equilibrium, which effects the associated first form of defect, namely poor melting, especially since high-melting intermetallic phases which include silver may form.

Therefore, according to one embodiment of the invention, in the underlying adjacent layers of the rear side coating of the silicon wafer or the silicon chip, the silver content is completely avoided, and instead a layer of gold is provided, the thickness of the gold layer being selected in such a way that the entire system comprising applied adapted gold coating and applied layer of a gold/tin solder material corresponds to the eutectic composition of the gold/tin system comprising 20% by weight tin and 80% by weight gold. The substitution of the silver-containing layer with gold on the one hand allows accurate setting of the eutectic composition and on the other hand prevents the formation of intermetallic binary silver/tin or ternary gold/silver/tin phases in the boundary layers. As extensive test have been able to demonstrate, the occurrence of these phases shifts the melting point of the system toward higher temperatures, so that a rear side coating of this type on a semiconductor wafer can no longer be reliably connected to a contact connection region of a circuit carrier.

In the above-mentioned process of the prior art, although the phase formation is prevented by cooling of the wafer, resulting in a reduction in the diffusion of silver into the gold/tin solder material, the cold application of the gold/tin solder layer increases the risk of poor bonding of the gold/tin solder layer to the silver, since wafer cooling is required for cold application of the gold/tin layer, but this then causes the second defect mechanism, i.e. the peeling.

Therefore, the silicon wafer according to the invention with the rear side coating according to the invention allows problem-free, successful further processing thereof to form semiconductor chips and ultimately a problem-free and reliable mounting on a corresponding contact connection region of a circuit carrier in order to build up a reliable and functioning semiconductor device.

In one embodiment of the invention, the volume of gold in the gold coating together with the volume of gold in the solder material in relation to the volume of tin in the solder material has a material composition of 80% by weight gold and 20% by weight tin. This requires a correspondingly higher tin content in the gold/tin solder material.

In one embodiment, the invention relates to a silicon chip with integrated circuit on its active top side and a solderable coating on its rear side, which includes a layer of a gold/tin solder material. The rear side coating of the silicon chip is free of silver constituents in the immediate vicinity of the solder coating, and the gold/tin solder material is arranged on an adapted gold layer. The volume of gold in the adapted gold coating, together with the volume of gold in the solder material, in relation to the volume of tin in the solder material is in thermodynamic equilibrium for a eutectic melt system comprising gold and tin.

By matching or adapting the gold/tin solder material and the gold coating to one another in this way and deriving the thicknesses of the gold coating and the coating thickness and the composition of the gold/tin solder material therefrom, results in a reliable way of reliably accommodating a semiconductor chip of this type in a corresponding package of a semiconductor device and optimizing it with a contact connection region of a circuit carrier both with respect to the thermal contact resistance and with respect to the electrical contact resistance. This also results in that it is possible to avoid the need to discard entire mounting batches in manufacture since the remelting of the eutectic gold/tin solder coating can take place reproducibly at a low eutectic melting temperature in thermodynamic equilibrium and without using silver-containing intermetallic phases.

In this context, a mounting batch is to be understood as meaning the total number of semiconductor devices produced on a single semiconductor wafer. A mounting batch may furthermore also comprise a complete set of silicon wafers coated under identical conditions in an evaporation coating unit or a sputtering unit.

The same considerations apply to the silicon chip as to the silicon wafer, namely that the volume of gold in the gold coating together with the volume of gold in the solder material in relation to the volume of tin in the solder material has a material composition of 80% by weight gold and 20% by weight tin, in order to achieve the thermodynamic equilibrium.

A further embodiment of the invention relates to a semiconductor device which has a silicon chip which is soldered by way of its rear side onto a contact connection region, a gold/tin solder material being arranged between the contact connection region and the rear side of the semiconductor chip, and neither the contact connection region nor the rear side of the silicon chip, adjacent to the gold/tin solder material, having a silver-containing coating. In one embodiment, the silicon chip in the semiconductor device has a bonding electrically conducting metal layer of aluminum which is covered by a diffusion-inhibiting metal coating of titanium.

In one embodiment, the adapted gold coating, on which there is also a layer of the gold/tin solder material with a tin content that is dependent on the total gold content in the gold layer and the gold/tin solder material, is applied to this titanium layer. A gold layer which is located on the contact connection region of the circuit carrier of the semiconductor device may also be included in the quantity of gold to be taken into account, in which case a diffusion-inhibiting electrically conducting layer of nickel phosphide may be arranged between this additional gold coating and the metal of the contact connection region if the contact connection region preferably includes copper or a copper alloy.

This embodiment of the invention has the advantage that the rear side coating and also the coating of the contact connection region in the semiconductor device is completely free of silver and therefore it is impossible for any binary or ternary intermetallic phases between silver, gold and/or tin, which have an embrittling effect or reduce the melting temperature and put the functionality of the semiconductor device at risk, to be formed.

A process for coating a silicon wafer which has integrated circuits on its wafer top side and has a wafer rear side which has a multi layer rear side coating that includes at least one gold/tin solder material is characterized by the following process.

A silicon wafer which has integrated circuits on its wafer top side and has a wafer rear side is produced. A bonding metal coating with an ohmic contact junction that is free of silver constituents is applied to the silicon wafer rear side. A diffusion-inhibiting metal layer is deposited on the conductive metal layer. An adapted gold coating is applied to the diffusion-inhibiting metal coating, the thickness of the adapted gold coating being adapted to the volume of gold in a gold/tin solder material which is subsequently applied, and the volume of gold in the adapted gold coating together with the volume of gold in the gold/tin solder material being in thermodynamic equilibrium in a eutectic melt system of gold and tin.

When the adapted gold coating is being applied and/or when the gold/tin solder coating is being applied, it should be noted that the silicon wafer is not cooled, and consequently the kinetic energy, which is converted into heat when the deposited metal particles come into contact with the surfaces to be coated and leads to near-surface heating, causes remelting of the gold/tin solder material and therefore peeling, which is a cause of defects, is avoided.

In one embodiment, the bonding metal coating applied with an ohmic contact junction to the silicon wafer is an aluminum layer or an aluminum alloy layer. Aluminum rear side coatings of this type have proven suitable as ohmic contact junctions in semiconductor technology.

In one embodiment, the diffusion-inhibiting metal layer applied is a titanium layer. Titanium layers of this type prevent the metal of the bonding layer from being able to diffuse into the region of the solder layer during soldering.

A process for producing a semiconductor device with a circuit carrier which has a contact surface for a silicon chip to be soldered onto is distinguished by the following process.

A silicon chip which has integrated circuits on its active top side and has a rear side is produced by dividing up a corresponding semiconductor wafer. The rear side has a bonding and conductive metal coating which is free of silver constituents and has a diffusion-inhibiting metal layer arranged on it. A diffusion-inhibiting metal layer is likewise applied to the contact connection region of the circuit carrier. An adapted gold coating is applied to one of the diffusion-inhibiting metal layers, the thickness of the adapted gold coating being adapted to the volume of gold in a gold/tin solder material which is subsequently applied, the volume of gold in the adapted gold coating together with the volume of gold in the solder material in relation to the volume of tin in the solder material corresponding to the eutectic melt system comprising gold and tin in thermodynamic equilibrium.

During the application of the gold/tin solder material, it is preferable to use a sputtering process, in which case, by omitting wafer cooling during the sputtering process, a molten liquid phase comprising gold coating and the gold/tin solder material is formed, so that after cooling the result is a gold/tin layer in which the thermodynamic equilibrium is established. This composition has a defined melting point at 278° C. and forms significantly improved bonding to the diffusion-inhibiting layer below, so that the risk of peeling is significantly reduced.

In one execution example of the process, the silicon chip is soldered onto the contact connection region of the circuit carrier with the aid of the gold/tin solder material provided. For this purpose, the entire system is heated to a temperature TP between 280° C.≦TP≦340° C., preferably between 280° C.≦TP≦320° C.

Furthermore, in one embodiment, the process for producing a semiconductor device having a semiconductor chip of this type is concluded by, after application of the silicon chip to the contact surface of the circuit carrier, the remaining contact surfaces on the active top side of the silicon chip being electrically connected to corresponding contact connection surfaces on the circuit carrier via internal connecting elements. This electrical connection is achieved using connecting elements having bonding wires.

In a further process for producing a semiconductor device with the corresponding silicon chip, after the internal connecting elements have been applied, the silicon chip and the connecting elements as well as subregions of the circuit carrier are packaged in a plastic packaging compound. As an alternative to being cast into or embedded in a plastic packaging compound, it is possible for the contact connection region, onto which the semiconductor chip is soldered, and also the contact connection surfaces for the remaining contact surfaces which are present on the active top side of the silicon chip, to be arranged in cutouts in a ceramic housing, in which case, finally, the cutout in the ceramic housing is closed off by preferably a metal plate.

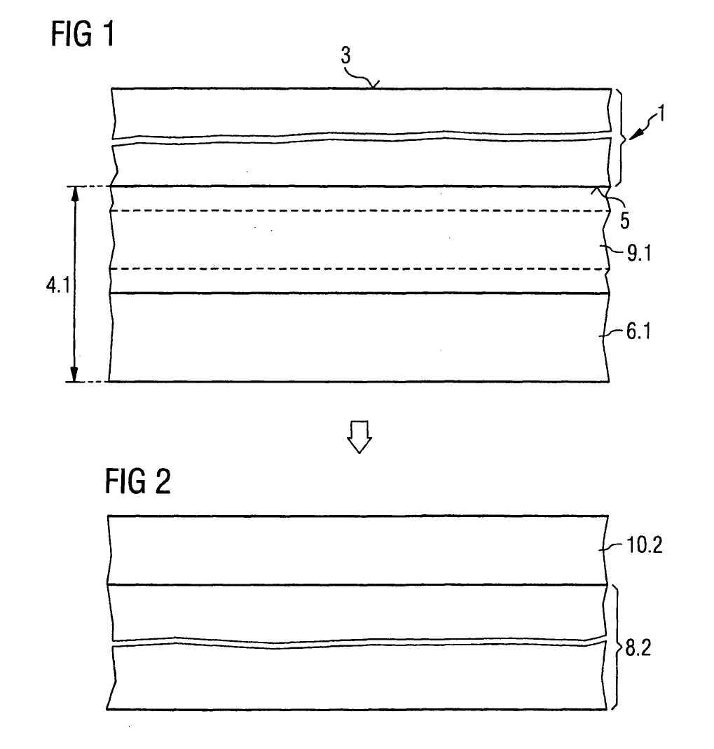

FIGS. 1 and 2, which diagrammatically depict the prior art, have already been explained above.

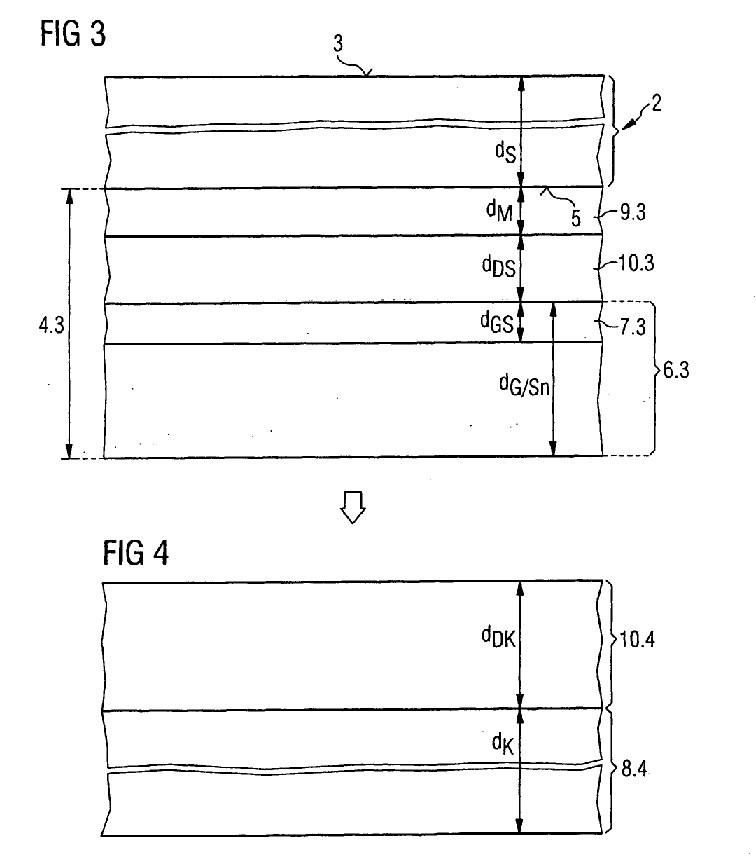

FIG. 3 illustrates a diagrammatic cross section through a silicon wafer or a silicon chip 2 of a semiconductor device in accordance with one embodiment of the invention. This embodiment of the invention illustrates a rear side coating 4.3 which is applied to a silicon semiconductor wafer and, after the silicon semiconductor wafer has been divided into individual silicon chips 2, also represents the rear side coating 4.3 of the silicon chip. This rear side coating 4.3 comprises a plurality of individual coating layers, which for their part have different thicknesses and different metals. The processes used to apply these coating layers to the rear side 5 of the silicon wafer and therefore to the rear side of the silicon chip 2 may also differ from one another.

In the vicinity of the top side 3 of the silicon wafer or the silicon chip 2, the latter have integrated circuits. The thickness dS of the silicon wafer may be between 280 μm≦dS≦1500 μm. The thickness ds of a corresponding silicon chip may be of the same thickness or may be thin-ground prior to further processing, so that thicknesses between 50 μm≦dS≦1500 μm are also possible. In this embodiment of the invention, an aluminum-containing layer with a thickness dm of approximately 500 nm has also been deposited on the rear side 5 of the silicon wafer or the silicon chip 2.

The deposition process in this embodiment of the invention is carried out by evaporation coating with aluminum or an aluminum alloy onto the rear side 5 of the silicon wafer. This aluminum coating on silicon results in ohmic contact with the silicon material and to improve bonding may include 1% by weight to 4% by weight silicon in the aluminum alloy. A diffusion-inhibiting coating 10.3 with a thickness dDS of approximately 700 nm, which includes titanium, has been applied to this bonding and ohmic metal coating 9.3. During the soldering process, this titanium layer prevents aluminum from being able to diffuse through to the solder coating.

A gold coating 7.3 with a thickness dGS of approximately 400 nm has been applied to the diffusion-inhibiting metal coating 10.3. This gold coating 7.3 can likewise be applied by evaporation coating technology. Then, a coating of a gold/tin solder material 6.3 with a thickness dG/Sn of approximately 1200 nm is applied by being deposited with the aid of a sputtering technique, during which, however, the silicon wafer is not cooled, so that a molten liquid gold/tin alloy 6.3 can form. During the application of the gold/tin solder material 6.3 for example by means of a sputtering technique, the gold coating 7.3 and the gold/tin solder material react in thermodynamic equilibrium to form a eutectic Au—Sn-layer 6.3 in accordance with the present invention, and therefore during further processing in subsequent processes can be remelted at the low eutectic melting temperature without high-melting intermetallic phases comprising silver having formed, especially since silver is not present in the rear side coating of the silicon wafer or silicon chip according to the invention. It is therefore advantageously possible to achieve a reliable soldered connection between, for example, leadframe and silicon chip or wiring substrate and silicon chip.

The basis for the thickness dimension dGS of the gold coating 7.3 and the thickness dimension dG/Sn of the gold/tin solder layer 6.3 is the fact that a thermodynamic equilibrium for a eutectic melt composition of gold and tin is achieved during the sputtering of the uncooled silicon wafer.

If there is no additional gold coating for protecting a contact connection region on a substrate or leadframe, the thickness dGS of the gold coating is matched to the thickness dG/Sn and the composition of the gold/tin solder coating in such a manner that the thermodynamic equilibrium between the gold content and the tin content is already maintained on the silicon chip side.

FIG. 4 illustrates a diagrammatic cross section through a contact connection region 8.4 of a circuit substrate of the semiconductor device in accordance with the one embodiment of the invention. The contact connection region 8.4 has a thickness dK and consists of a metal with a good conductivity, such as copper or aluminum or alloys thereof. If this conductive metal, as in the present embodiment of the invention, is formed from copper, a layer of nickel phosphide is applied to the copper material as diffusion-inhibiting layer 10.4, with a thickness dDK of approximately 2 μm. To protect the nickel phosphide layer from corrosion and oxidation, it is also possible for a gold layer 7.4 with a thickness dGK of approximately 200 nm to be applied to the diffusion-inhibiting layer 10.4.

A leadframe may include copper or a copper alloy and silver-coated contact connection regions. In this case, the silver layer may have a thickness of approximately 5 μm. This silver layer on regions of the leadframe, unlike a silver layer on the silicon rear side, does not disrupt the soldering process, since this soldered connection to the leadframe is definitive and no remelting of a gold/tin solder, such as on the rear side of silicon chips in the process for producing semiconductor devices, is required.

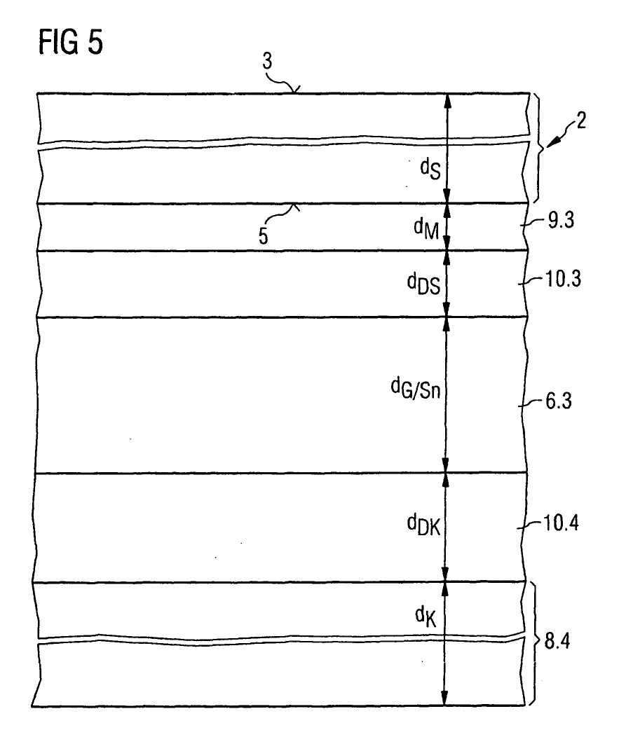

FIG. 5 illustrates a diagrammatic cross section through a silicon chip 2 on a contact connection region 8.4 of a circuit substrate of the semiconductor device according to the one embodiment of the invention. For this purpose, the silicon chip 2 as shown in FIG. 3 was soldered onto the contact connection region 8.4 shown in FIG. 4 by being applied in arrow direction A between FIGS. 3 and 4 followed by heating to a process temperature TP between 280° C.≦TP≦340° C. This forms a soldering layer of a gold/tin material 6.3 which has a thickness dG/Sn of approximately 1600 nm, the composition of which corresponds to the thermodynamic equilibrium of the eutectic melt of tin and gold.

The gold/tin solder material 6.3 between the silicon chip 2 and the contact connection region 8.4 is adjoined by the respective diffusion inhibiting layers 10.4 and 10.3 which, as mentioned above, on the side of the silicon chip have a thickness dDS of approximately 700 nm of titanium and on the contact connection region 8.4 have a thickness dDK of 2 μm of nickel phosphide. The abovementioned bonding and contact-providing metal coating 9.3 with a thickness dM of approximately 500 nm of aluminum is arranged between the silicon substrate 2 and the diffusion-inhibiting layer 10.3 of titanium.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A silicon wafer comprising:
a wafer top side with integrated circuits; and
a wafer rear side with a solderable coating, comprising a gold/tin solder material, the rear side coating being free of silver constituents in the immediate vicinity of the solderable coating, and the gold/tin solder material being arranged on an adapted gold coating, the volume of gold in the adapted gold coating, together with the volume of gold in the solder material in relation to the volume of tin in the solder material corresponding to the eutectic melt system of gold and tin in thermodynamic equilibrium.

2. The silicon wafer as claimed in claim 1, comprising wherein the volume of gold in the gold coating together with the volume of gold in the solder material in relation to the volume of tin in the solder material comprises a material composition of 80% by weight gold and 20% by weight tin.

3. A silicon chip comprising:
an integrated circuit on an active top side; and
a solderable coating on a rear side, comprising a gold/tin solder material, the solderable coating being free of silver constituents in the immediate vicinity of the solder coating, and the gold/tin solder material being arranged on an adapted gold coating, the volume of gold in the adapted gold coating together with the volume of gold in the solder material in relation to the volume of tin in the solder material corresponding to the eutectic melt system of gold and tin in thermodynamic equilibrium.

4. The silicon chip as claimed in claim 3, comprising wherein the volume of gold in the gold coating together with the volume of gold in the solder material in relation to the volume of tin in the solder material comprises a material composition of 80% by weight gold and 20% by weight tin.

5. A semiconductor device having the silicon chip as claimed in claim 3 soldered by way of its rear side onto a contact connection region, a gold/tin solder material being arranged between the contact connection region and the rear side of the semiconductor chip, and the rear side of the silicon chip not having a silver-containing coating adjacent to the gold/tin solder layer.

6. A process for coating a silicon wafer, with a multilayer rear side coating which comprises at least one gold/tin solder material, the process comprising:
producing a silicon wafer, which comprises integrated circuits on its wafer top side and comprises a wafer rear side;
applying a bonding metal coating with an ohmic contact junction with the silicon wafer, which bonding metal coating is free of silver constituents, to the rear side of the silicon wafer;
applying a diffusion-inhibiting metal layer to the conductive metal coating; and
applying an adapted gold coating to the diffusion-inhibiting metal layer, the thickness of the adapted gold coating being adapted to the volume of gold of a gold/tin solder material which is subsequently applied, the volume of gold in the adapted gold coating together with the volume of gold in the solder material in relation to the volume of tin in the solder material corresponding to the eutectic melt system comprising gold and tin in thermodynamic equilibrium.

7. The process as claimed in claim 6, wherein the diffusion-inhibiting metal layer applied is a titanium layer.

8. The process as claimed in claim 6, wherein the bonding metal coating with ohmic contact junction with the silicon wafer applied is an aluminum layer or an aluminum alloy layer.

9. The process as claimed in claim 8, wherein the diffusion-inhibiting metal layer applied is a titanium layer.

10. A process for producing a semiconductor device with a circuit carrier, which comprises a contact connection region for a silicon chip to be soldered onto, the process comprising:
producing a silicon chip which comprises at least one integrated circuit on its active top side and has a rear side, the rear side having a bonding and conducting metal coating, which is free of silver constituents, and a diffusion-inhibiting metal layer;
applying a diffusion-inhibiting layer to the contact connection surface; and
applying an adapted gold coating to the diffusion-inhibiting metal layer, the thickness of the adapted gold coating being adapted to the volume of gold of a gold/tin solder material which is subsequently applied or is provided on the rear side of the silicon chip, the volume of gold of the adapted gold coating together with the volume of gold in the solder material in relation to the volume of tin in the solder material corresponding to the eutectic melt system comprising gold and tin in thermodynamic equilibrium.

11. The process as claimed in claim 10, comprising wherein the diffusion-inhibiting layer applied is a titanium coating and/or a nickel phosphide layer.

12. The process as claimed in claim 10, comprising wherein the gold/tin solder material is applied to the adapted gold coating by sputtering without cooling of the silicon wafer or the silicon chip.

13. The process as claimed in claim 10, comprising wherein the silicon chip is soldered onto the contact connection region with the aid of the gold/tin solder material provided.

14. The process as claimed claim 10, comprising wherein after the silicon chip has been soldered onto the contact connection region of the circuit carrier, the contact surfaces on the top side of the silicon chip are electrically connected to corresponding contact connection surfaces on the circuit carrier via internal connecting elements.

15. The process as claimed in claim 14, comprising wherein after internal connecting elements have been attached, the silicon chip and the connecting elements as well as subregions of the circuit carrier are packaged in a plastic packaging compound.

16. The process as claimed in claim 10, comprising wherein the gold/tin solder material is applied to the adapted gold coating by sputtering without cooling of the silicon wafer or the silicon chip, and wherein the silicon chip is soldered onto the contact connection region with the aid of the gold/tin solder material provided.

17. The process as claimed claim 16, comprising wherein after the silicon chip has been soldered onto the contact connection region of the circuit carrier, the contact surfaces on the top side of the silicon chip are electrically connected to corresponding contact connection surfaces on the circuit carrier via internal connecting elements.

18. The process as claimed in claim 17, comprising wherein after internal connecting elements have been attached, the silicon chip and the connecting elements as well as subregions of the circuit carrier are packaged in a plastic packaging compound.

19. A silicon wafer comprising:
a wafer top side with integrated circuits; and
a wafer rear side with means for providing a solderable coating, comprising a gold/tin solder material, the rear side coating being free of silver constituents in the immediate vicinity of the solderable coating, and the gold/tin solder material being arranged on an adapted gold coating, the volume of gold in the adapted gold coating, together with the volume of gold in the solder material in relation to the volume of tin in the solder material corresponding to the eutectic melt system of gold and tin in thermodynamic equilibrium.

20. The silicon wafer as claimed in claim 19, comprising wherein the volume of gold in the gold coating together with the volume of gold in the solder material in relation to the volume of tin in the solder material comprises a material composition of 80% by weight gold and 20% by weight tin.
